(19) United States
(12) Patent Application Publication
(10) Pub. No.: US 2010/0217552 A1
(43) Pub. Date: Aug. 26, 2010

(54) Battery Management System for Measuring Remaining Charges in a Battery Packet with Multi-Cells

(75) Inventors: Hung-An Hsu, Zhu-Dong Town (TW); Tzong-Liang Shiue, Jhubei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: NEOTEC SEMICONDUCTOR LTD., Chu-Pei (TW)

(21) Appl. No.: 12/709,689

(22) Filed: Feb. 22, 2010

(30) Foreign Application Priority Data
Feb. 23, 2009 (TW) 98105739

(51) Int. Cl. G01R 31/36; G06F 19/00

(52) U.S. Cl. 702/63

(57) ABSTRACT

A battery management system for measuring remaining charges in a battery packet with multi-cells is disclosed. The battery comprises electric property and non-electric property measuring modules, multi-cells, a slave communication protocol controller, and a battery protective circuit. The portable device comprises an embedded controller and a charge gauge module and a master communication protocol controller. The parameters demanded for calculating the remaining charges of the multi-cells are measured by the electric property and non-electric property measurement modules and transferred through the SMBus interface to the embedded controller and the charge gauge module. Therefore, the battery management system can manage the remaining charges of every cell in the multi-cells without a microprocessor in the battery packet.

### BACKGROUND OF THE INVENTION

1. Field of the Invention

The present invention pertains to a battery management architecture, particularly to a battery management system having multi-cells battery.

2. Description of the Prior Art

In general, a portable electronic apparatus must contain a battery. The portable electronic apparatus are such as a cell phone, notebook, personal assistance (PDA), walker-man etc. However, the battery carries a finite amount of charges and the charges will be persisting consumed while the portable electronic apparatus is in use. For a battery with a good management, the power of the portable electronic apparatus will be enforced to turn off while the charge remnant is lower than a critical value so as to protect the battery from over discharging. The battery will then need charging again to renew.

A battery system with a good management can provide a battery to be recharged for over several hundreds of times. On the other hand, a charging sustainability of a battery is often served as an index to judge quality of a notebook has. Therefore, the battery having multi-cells such as three four or six is in common for most of best seller notebooks so as to increase the charge capacity. Since the cells are arranged in parallel and in series so that the variation of the chemistry in the cells may vary, as a result, the available charging capacity for one cell may be different from another after using a periods of time. Consequently, they will affect the life-time of the battery and it thus more complicity of the battery management than that of the battery with single cell or two cells.

Referring to FIG. 1, it shows a schematic architecture of a battery management system for a battery packet with multi-cells and for a corresponding notebook. In FIG. 1, the battery packet comprises multi-cells 15, a battery protective integrated circuit 20, a battery property detecting module 25, a battery charge gauge module 30, a slave SMBus controller 40s, terminals P+and P−. The battery through the terminals P+ and P− processes charging or outputs charges thereof to the NB 50. The protective circuit 20 usually contains an over-charging comparator, over-discharging comparator, over-current comparator, and MOSFETs. The battery property detecting module 25 consists of an electrical property measuring module 25b and a non-electrical property measuring module 25a. The non-electrical property measuring module 25a are, such as, the temperatures atop the surfaces of the cells and the electrical property measuring module 25b is provided to detect output voltages of every node of the cells. The battery charge gauge module 30 includes a microprocessor. The microprocessor fetches the detected data such as voltages, currents, temperatures and accordingly, calculates the remaining charges in the battery by using the program stored in the electrically erasable programable read only memory (EEPROM) or flash memory. As to the slave SMBus control 40s is a commutation interface between the NB 50 and the battery packet 10 thereof embedded in the battery packet 10.

On the other hand, the NB 50 comprises a master SMBus control 40m and an embedded controller, hereinafter called EC 45, corresponding to the battery packet 10. The master SMBus controller 40m and the slave SMBus controller 40s as their names have a master-slave relationship. The master SMBus controller 40m inquires the data about remaining charges in the battery 15 but the slave SMBus controller 40s can only respond that passively.

For a notebook 50 is concerned, the EC 45 is embedded in the keyboard controller. Distinct from the desktop personal computer, the keyboard controller usually contains a microprocessor, which is combined with the master SMBus controller 40m to request the data about the battery capacity so that the EC 45 can provides remaining charges of the battery to the operation system and manage the battery alone without consuming the resource of the central process unit (CPU) of the NB 50.

A second embodiment about multi-cells battery management in accordance with the prior art is shown in FIG. 2.

In FIG. 2, the battery packet 210 has multi-cells 215, a battery protective IC 220, a non-electrical property measuring module 225a, a slave SMBus controller 240s. In the notebook 250, it has a master SMBus controller 240m, an EC and a battery charge gauge module 230, an electrical property measuring module 225b. The terminals P+ and P− are the same as above.

The master SMBus controller 40m and the slave controller 40s have a master-slave relationship similar to the first embodiment. But the electric property measuring module 225b and the charge gauge module 230 are located in the notebook 250 carried out the matters relied on the hardware and the firmware in the EC 230 and battery charge gauge module 230. For instance, the electric property measuring module 225b can acquire the voltage of the multi-cells through the P− terminal and the output terminal P+ of the battery protective IC 220. Hence, the data measured such as the terminal voltage, the charge current and discharge current of the multi-cells 215 are all for the entire multi-cells. As a result, the firmware of the EC and battery charge gauge module 230 can not conduct the management for individual cell.

By comparing the battery management shown in FIG. 1, the first embodiment with the second embodiment shown in FIG. 2, each owns its individual advantages and disadvantages. The cost for the battery management according to the second embodiment can be down since the measurement of the remaining charges in the battery can be conducted by means of the hardware and software of the EC and battery charge gauge module 230 but the main disadvantage is that it cannot measure the individual cell. This is in general inferior to a battery with multi-cells. The battery management according to the first embodiment is usually higher cost since the battery packet 10 is demanded to calibrate and measure the charges before leaving the factory, which are high time cost. In addition to the related measuring modules, a microprocessor is usually necessary built in the battery packet 10. It is another cost term.

As aforementioned, an object of the present invention is to disclose a battery management system with the benefits of both prior arts.

### SUMMARY OF THE INVENTION

A battery management system for measuring remaining charges in a battery packet with multi-cells is disclosed. The management system has a battery packet and a portable electronic device. The battery comprises electric property and non-electric property measurement modules, multi-cells, a slave communication protocol controller, and a battery protective circuit and the portable device comprises an embedded controller and a charge gauge module and a master communication protocol controller.

The portable device comprises an embedded controller and a master communication protocol controller. The parameters demanded for calculating the remaining charges of the multi-cells are measured by the electric property and non-electric property measurement modules and transferred through the SMBus interface to the embedded controller and the charge gauge module. Therefore, the battery management system can manage the remaining charges of every cell in the multi-cells without a microprocessor in the battery packet. Consequently, the lifetime of the battery can be longer and more security.

### BRIEF DESCRIPTION OF THE DRAWINGS

The present invention will be more fully understood from the detailed description, which will be given hereinafter, with the aid of the illustrations below:

FIG. 1 shows a battery management for a battery with multi-cells in accordance with a first embodiment of the prior art.

FIG. 2 shows a battery management for a battery with multi-cells in accordance with a second embodiment of the prior art.

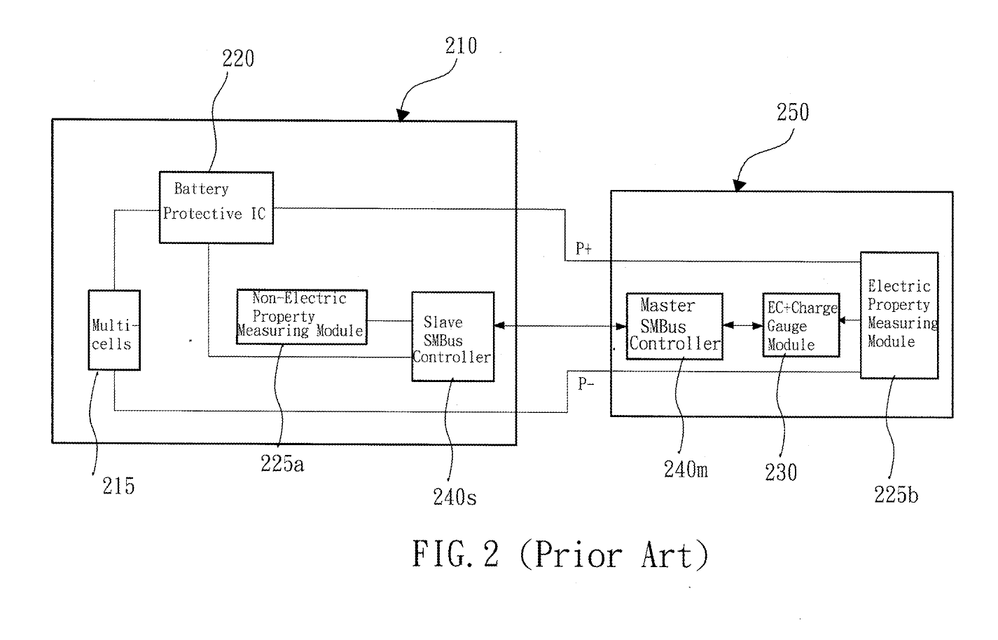

FIG. 3 shows a battery management for a battery with multi-cells in accordance with a preferred embodiment of the present invention.

FIG. 4 shows the function clocks in a battery packet in accordance with the present invention.

### DESCRIPTION OF THE PREFERRED EMBODIMENT

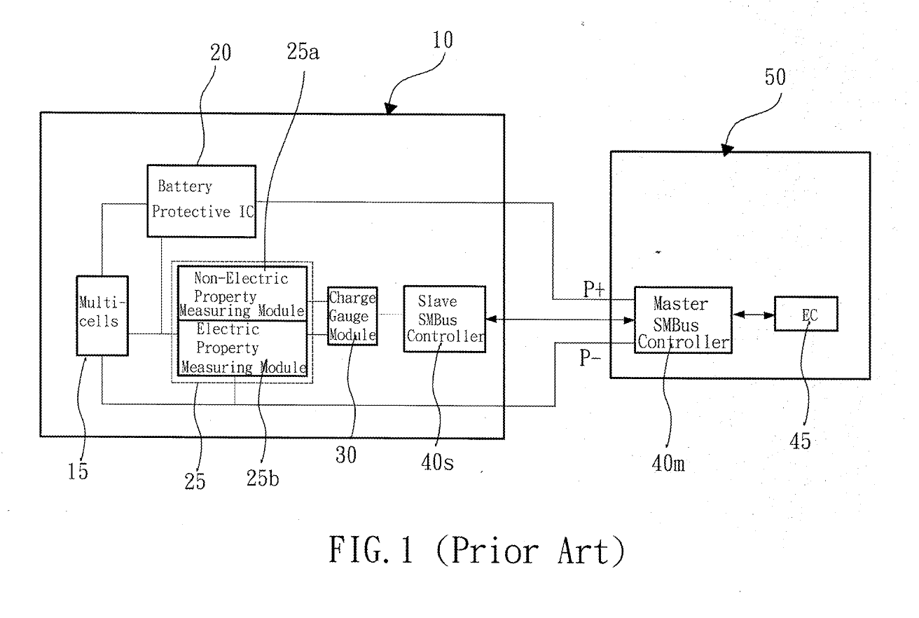

As forgoing depictions in the background of the invention, the advantages existed in the first battery management architecture shown in FIG. 1 but may be inferior in the cost. Similarly, the second battery management architecture improves the issue about cost but the benefits of the first battery management architecture are disappeared. The present invention discloses a novelty battery management architecture including advantages of two prior arts.

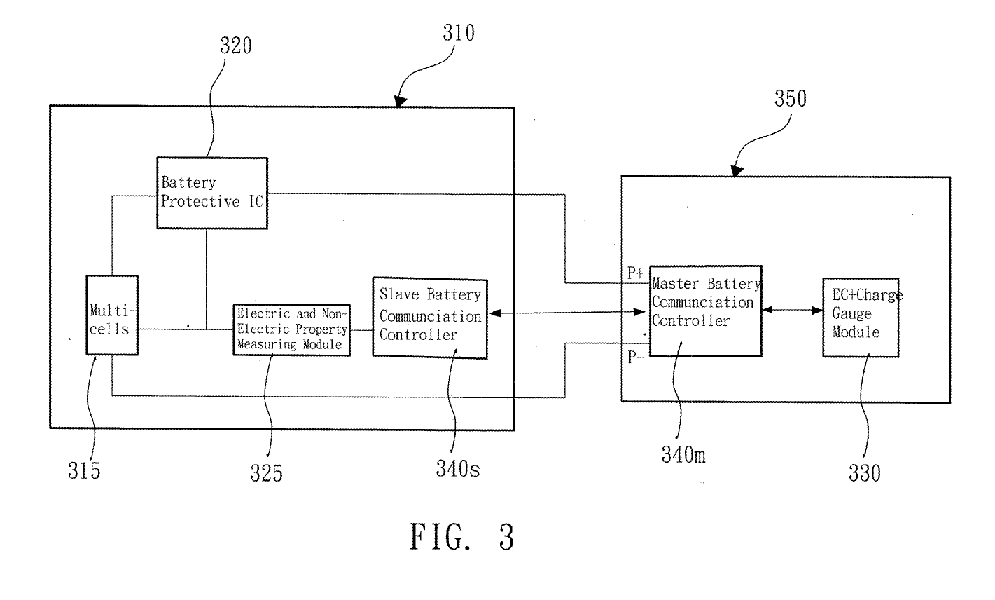

Please refer to FIG. 3, the function blocks for a battery packet 310 is shown. The battery packet 310 includes multi-cells 315, battery protective IC 320, an electric property and non electric property measuring modules 325, a slave battery communication protocol controller 340s. The portable electric apparatus 350 such as notebook includes an EC (embedded controller) and a charge gauge module 330 and a master battery communication protocol controller 340m. The battery communication protocol controller 340m, 340s may be a SMBus or others such as I²C or HDQ. The P+ and P− are voltage terminals of the battery packet 310. The EC 330 is built in the keyboard controller.

Herein, the electric property and non electric property measuring modules 325 are included in the battery packet 310 the same as the first battery management architecture in FIG. 1. However, the charge gauge module is disposed in the notebook 350 instead. No microprocessor is included in the battery packet 310. The remaining charges in the multi-cells 315 can be calculated, monitoring, and managed by the microprocessor and the software of the EC and charge gauge module 330 associated with the operation system of the notebook through the data received by the master SMBus controller 340m.

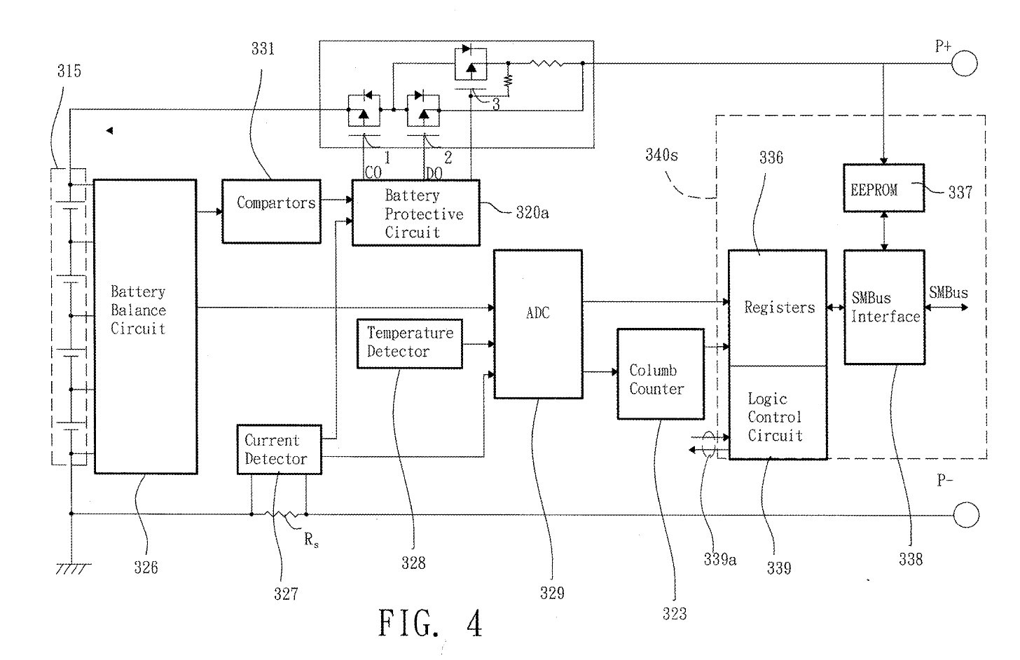

FIG. 4 shows the detailed circuitry of the function blocks. The battery protective IC 320 includes a battery protective circuit 320a, which usually involves driver and delayed circuit, a voltage comparators 331, transistors FET1, FET2, and FET3 so as to protect the battery. The voltage comparators 331 include a plurality of voltage comparators so as to compare data of the terminal voltage of each cell with a reference voltage.

The electric property and non electric property detecting modules 325 comprise a current detecting circuit 327, temperature detector 328, ADC (analog to digital converter) 329 and Coulomb counter 323. The ADC 329 fetches sequentially the data including the voltage drop across the resistor Rs of each cell of the multi-cells 315 and a voltage detected by a temperature detector in a way of multi-task and time sharing. After converting, the digital data are stored in the registers 336. The temperature detector 328 is to detect the surface temperature of the multi-cells. The battery balance circuit 326 is to detect the analog voltage of the individual cell and the current detector 327 measures the current over the resistor Rs. The cross voltage over the resistor Rs is then converted by ADC 329 and calculated through the coulomb counter 323 to execute calculate about charge cumulate (while charging) or de-cumulated (while discharging). The results are stored back to the registers 336 which are equivalent to the current of each cell in the multi-cells 315.

Preferably, the slave battery communication protocol controller 340s is a SMBus controller. The battery packet 310 includes also registers 336, electricly erasable programmable read only memory (EEROM) 337, a logic control circuit 339, a SMBus interface 338. The EEPROM 337 is provided for storing some characteristic parameters about the battery packet 310. The EC transfers the commands for battery packet control via the SMBus to drive the function blocks through the logic control circuit 339, and bus 339a. Note some of the connection lines are not shown in the FIG. 4 to avoid line crowed.

The internal operations about the battery packet 310 are as followings: Firstly, with respect to the cell balance function, the first control parameters for the battery packet management are sent to registers 336 through SMBus interface 338 from the SMBus controller 340m of the NB 250. Upon the first control parameters in the registers 336 received by the logic control circuit 339, the first control parameters are transferred to the battery balance circuit 326 through the bus 339a. The battery balanced circuit 326 utilizes the first control parameters control the charging and discharging of each cell. While a voltage of one of multi-cells reaching a first predetermined threshold, the charges charging to the cell are ended but the charging to the others are sustained. On the other hand, if the multi-cells are discharging and one of them reaching a second predetermined threshold, the discharging to the cell will be forbidden and the others continuous so that the battery balanced circuit 326 is provided to kept every cell with almost the same remaining charges.

The battery balanced circuit 326 provided to keep every cell with almost the same voltage is necessary. Since the polymerized properties of the stuffed chemistries in every cell may present variance after aging. Without the battery balanced circuit 326, the charging capacities may be reduced just due to one of the multi-cells is premature deterioration.

With respect to the battery packet protection by the battery management system, the second control parameters for battery management are prepared. Likes the first control parameters, they are also sent to registers 336 through SMBus interface 338 from the SMBus controller 340m of the NB 250. Upon the second control parameters in the registers 336 received by the logic control circuit 339, the second control parameters are transferred to the voltage comparators 331 through the bus 339a. The output results of the voltage comparators 331 are then sent to battery protect circuit 320a to provide control signals for the charging switch FET1 and the discharging switch FET2. They are MOSFETs and with gates thereof, respectively, connected to the pins CO and DO of the battery protect integrated circuit 320.

When any one of the cells has a voltage reaches a third predetermined threshold, the charging switch FET1 is turned OFF so as to stop the battery packet 310 from charging. When any one of the cells has a voltage reaches a fourth predetermined threshold, the charging switch FET2 is turned OFF so as to stop the battery packet from discharging.

In other word, the second control parameter is provided to control the charging and discharging of the whole battery packet. Whereas the first control parameters are provided to control the charging and discharging of one of the cells in the multi-cells.

The benefits of the present invention include:
1. The cost of a microprocessor in the battery packet can be saved, which is usually provided for calculating the remaining charges, herein the task is carried out by the EC of the portable device.
2. Each cell of the multi-cells can be measured individually so that the battery management is getting better and the life time of the battery can be extended.
3. the testing cost of the battery packet can be reduced

As is understood by a person skilled in the art, the foregoing preferred embodiment of the present invention is an illustration, rather than a limiting description, of the present invention. It is intended to cover various modifications and similar arrangements included within the spirit and scope of the appended claims, the scope of which should be accorded the broadest interpretation so as to encompass all such modifications and similar structures.

What is claimed is:

1. A battery management system for measuring remaining charges in a battery packet with multi-cells comprising:
a battery packet having multi-cells for a portable device, electric property and non-electric property measuring modules, a slave communication protocol controller, and a battery protective integrated circuit, wherein said electric property and non-electric property measuring modules are connected in between said multi-cells and the slave communication protocol controller to provide data of electric property and non-electric property of every cell in said multi-cells and said data are transferred to said slave communication protocol controller, further, said slave communication protocol controller provided to receive first control parameters and second control parameters from the portable device so as to manage said multi-cells;
a charge gauge module and a master communication protocol controller installed in the portable device, said master communication protocol controller inquiring said data of electric property and non electric property of every cell and calculating remaining charging of each cell of said multi-cells and transferring said first parameters and said second parameters to said slave communication protocol controller.

2. The battery management system according to claim 1, wherein said data of electric property and non-electric property comprises the terminal voltage of every cell of said multi-cells.

3. The battery management system according to claim 2, wherein said data further comprises output current from every cell and input current into every cell of said multi-cells.

4. The battery management system according to claim 1, wherein said first control parameters are provided to control charging and discharging of every cell of said multi-cells.

5. The battery management system according to claim 1, wherein said second control parameters are provided to control charging and discharging of said battery packet.

6. The battery management system according to claim 1, wherein said charge gauge module is installed at an embedded controller of said portable device.

7. The battery management system according to claim 6, wherein said charge gauge module is in a form of software or firmware written in said embedded controller.

8. The battery management system according to claim 6, wherein said embedded controller is installed in a key board controller of said portable device.

9. The battery management system according to claim 1 wherein said master and slave communication protocol controllers are selected from the group consisting of SMBus, I²C, and HDQ.

10. The battery management system according to claim 1 wherein said electric property and non-electric property measuring modules comprise a coulomb counter to count current into and out from every cell of said multi-cells.
